(19) United States
(12) Patent Application Publication
(10) Pub. No.: US 2007/0146023 A1
(43) Pub. Date: Jun. 28, 2007

(54) Reset signal generating circuit and semiconductor integrated circuit device

(76) Inventor: Masanori Miyagi, Chiba-shi (JP)

Correspondence Address: BRINKS HOFER GILSON & LIONE, P.O. BOX 10395, CHICAGO, IL, 60610, US

(21) Appl. No.: 11/542,502

(22) Filed: Oct. 3, 2006

(30) Foreign Application Priority Data
Oct. 7, 2005 (JP) JP2005-294938
Feb. 8, 2006 (JP) JP2006-031212

(51) Int. Cl. H03L 7/00

(52) U.S. Cl. 327/142

(57) ABSTRACT

Provided is a semiconductor integrated circuit device including a reset signal generating circuit for detecting a plurality of power source voltages in which a consumption current is low and a circuit area is small. The semiconductor integrated circuit device includes the reset signal generating circuit. The reset signal generating circuit includes a plurality of voltage detecting circuits whose consumption currents are not changed even when a power source voltage significantly changes, in which output signal terminals of the voltage detecting circuits are connected with gate electrodes of a plurality of N-channel enhancement MIS transistors connected in series with an output node of a current mirror circuit to simultaneously perform an amplification and a logical operation on output signals of the voltage detecting circuits, to thereby realize low power consumption even in a wide operating voltage range and with a reduced circuit area.

This application claims priority under 35 U.S.C. § 119 to Japanese Patent Application Nos. JP2005-294938 filed Oct. 7, 2005, and JP2006-031212 filed Feb. 8, 2006, the entire content of which is hereby incorporated by reference.

### BACKGROUND OF THE INVENTION

1. Field of the Invention

The present invention relates to a semiconductor integrated circuit device which includes a plurality of circuit blocks respectively operating at different power source voltages and in which the operation of the plurality of circuit blocks is controlled by a circuit for detecting the respective different power source voltages and generating reset signals.

2. Description of the Related Art

With a reduction in process size for manufacturing a semiconductor integrated circuit, there is a tendency to reduce operating voltages in order to ensure the reliability of elements such as transistors. On the other hand, in the case of external signal communication, the operating voltages cannot be unconditionally reduced in an interface circuit interfacing with a conventional semiconductor integrated circuit. Therefore, for example, there is a case of employing a method of supplying, to an internal logic circuit and the like provided in the semiconductor integrated circuit, a low power source voltage obtained by reducing an external power source voltage through an internal step-down circuit, and supplying the external power source voltage to the interface circuit for operation.

In general, when a power source voltage of the semiconductor integrated circuit reduces to a value close to a threshold voltage of a transistor, the semiconductor integrated circuit malfunctions. That is, such the reduction in power source voltage causes the semiconductor integrated circuit to malfunction. Therefore, upon detecting a reduced power source voltage which is equal to or smaller than a specific power source voltage, it is necessary to reset the semiconductor integrated circuit to an initial safe state or fix a logic so that the semiconductor integrated circuit does not enter a dangerous operating mode. The semiconductor integrated circuit having the internal step-down circuit includes a circuit being operated by the external power source voltage and a circuit being operated by an internal step-down voltage. Thus, it is desirable that a reduction in external power source voltage and a reduction in internal step-down voltage be detected, and when at least one of the detected voltages is reduced to a value equal to or smaller than a specific voltage, the semiconductor integrated circuit be reset to the initial safe state or the logic be fixed so that the semiconductor integrated circuit does not enter the dangerous operating mode (see, for example, JP 2001-210076 A).

FIG. 7 is a circuit diagram showing an example of a conventional reset signal generating circuit.

A bias circuit 903, which is composed of a resistor 901 and a resistor 902, is connected with a terminal for an external power source voltage VEXT. A node N5, which is a connection point between the resistor 901 and the resistor 902, is connected with a gate electrode of an N-channel enhancement type MIS transistor 908. A voltage, which is obtained by dividing the external power source voltage by the resistor 901 and the resistor 902, is caused at the node N5. When the voltage of the node N5 becomes equal to or larger than a threshold voltage of the N-channel enhancement type MIS transistor 908, which is a constituent element of a waveform shaping section 909, a potential of a node N7, which is a connection point between the N-channel enhancement type MIS transistor 908 and a resistor 907, is changed from a high potential (VEXT) to a low potential close to a ground (GND) level. According to such the operation, a detection signal, which indicates that the external power source voltage VEXT is lower than a specific voltage, is caused at the node N7 with a negative logic.

Similarly, a bias circuit 906, which is composed of a resistor 904 and a resistor 905, is connected with a terminal for an internal step-down voltage VINT. Therefore, a bias voltage, which is obtained by dividing the internal step-down voltage, is caused at a node N6. When the bias voltage is applied to a gate electrode of an N-channel enhancement type MIS transistor 911, which is a constituent element of a waveform shaping section 912, a detection signal, which indicates that the internal step-down voltage is lower than the specific voltage, is caused at a node N8 with a negative logic.

Logic amplitudes of the voltages of the detection signal at the node N7 and the node N8 are amplified to VEXT-GND by amplifying circuits composed of inverters 913 and 914 and then inputted to a NAND circuit 915 to perform a logical operation. When at least one of the external power source voltage VEXT and the internal step-down voltage VINT is lower than the specific value, an LV_EXT signal, which is an output of the NAND circuit 915, becomes “H”.

In the conventional example shown in FIG. 7, each of the bias circuits 903 and 906 is composed of the resistors connected in simple series. In each of the waveform shaping sections 909 and 912, the resistor is connected in series with a drain electrode of the N-channel enhancement type MIS transistor. Therefore, a current flowing into each of the circuits is significantly changed according to changes in external power source voltage and internal step-down voltage.

In order to improve a transient response of the circuit with respect to the change in voltages, it is necessary to supply a certain amount of current to each of the bias circuits in the vicinity of a detection voltage. However, in the case of the semiconductor integrated circuit which requires to ensure the operation in a wide range of external power source voltage of, for example, 1.8 V to 5.5 V, the conventional voltage detecting circuit as shown in FIG. 7 has a problem in that a very large consumption current flows into the circuit when the external power source voltage is high.

When a plurality of interval step-down voltages are used, it is necessary to provide the voltage detecting circuits as many as the number of types of the interval step-down voltages. Therefore, a circuit area of a logical operation as well as the consumption current increase, so there is a problem in that a manufacturing cost increases.

### SUMMARY OF THE INVENTION

In order to solve the above-mentioned problems, according to a first aspect of the present invention, a reset signal generating circuit includes: a plurality of power source voltage detecting means; means for amplifying and waveform-shaping a plurality of input signals and performing a logical operation therebetween; and a level converting circuit for converting an amplitude of an output signal outputted from the means for amplifying and waveform-shaping the plurality of input signals and performing the logical operation into a specific logical amplitude. Each of the plurality of power source voltage detecting means includes: a constant current circuit; and a P-channel enhancement type MIS transistor whose source electrode is connected with a terminal for a power source potential to be detected, whose gate electrode is connected with a ground potential terminal, and whose drain electrode is connected with the constant current circuit. The means for amplifying and waveform-shaping the plurality of input signals and performing the logical operation includes: a current mirror circuit including at least one input terminal and at least one output terminal; a constant current circuit including an output terminal connected with the input terminal of the current mirror circuit; and a plurality of N-channel enhancement type MIS transistors connected in series with the output terminal of the current mirror circuit. The number of N-channel enhancement type MIS transistors is equal to the number of power source voltage detecting circuits. Output signals from the plurality of power source voltage detecting means are applied on a one-to-one basis to gate electrodes of the N-channel enhancement type MIS transistors which are connected in series and included in the means for amplifying and waveform-shaping the input signals and performing the logical operation.

In a reset signal generating circuit according to a second aspect of the present invention, the current mirror circuit of the first aspect includes a first P-channel enhancement type MIS transistor and a second P-channel enhancement type MIS transistor. A gate electrode of the first P-channel enhancement type MIS transistor and a gate electrode of the second P-channel enhancement type MIS transistor are commonly connected with each other and also connected with a drain electrode of the first P-channel enhancement type MIS transistor, thereby constructing the input terminal of the current mirror circuit. A drain electrode of the second P-channel enhancement type MIS transistor serves as the output terminal of the current mirror circuit. A source electrode of the first P-channel enhancement type MIS transistor and a source electrode of the second P-channel enhancement type MIS transistor are commonly connected with one of a plurality of power source voltages. The constant current circuit of the means for amplifying and waveform-shaping the plurality of input signals and performing the logical operation includes an N-channel depletion type MIS transistor having a gate electrode and a source electrode connected with the ground potential terminal.

According to a third aspect of the present invention, there is provided a semiconductor integrated circuit device including: means for reducing an external power source voltage supplied from an outside; a circuit block being operated by the external power source voltage; a circuit block being operated by an internal power source voltage obtained by reducing the external power source voltage; and a reset signal generating means. The reset signal generating means includes: a first detecting circuit for detecting the external power source voltage; a second detecting circuit for detecting the obtained internal power source voltage; a circuit for amplifying and waveform-shaping a plurality of input signals and performing a logical operation therebetween; a level converting circuit for converting an amplitude of an output signal from the circuit for amplifying and waveform-shaping the plurality of input signals and performing the logical operation into a logical amplitude corresponding to the external power source voltage; and a level converting circuit for converting the amplitude of the output signal into a logical amplitude corresponding to the internal power source voltage. Each of the circuit for detecting the external power source voltage and the circuit for detecting the obtained internal power source voltage includes: a constant current circuit; and a P-channel enhancement type MIS transistor whose source electrode is connected with a terminal for a power source potential to be detected, whose gate electrode is connected with a ground potential terminal, and whose drain electrode is connected with the constant current circuit. The circuit for amplifying and waveform-shaping the input signals and performing the logical operation includes: a current mirror circuit including at least one input terminal and at least one output terminal; a constant current circuit including an output terminal connected with the input terminal of the current mirror circuit; and a plurality of N-channel enhancement type MIS transistors connected in series with the output terminal of the current mirror circuit. The number of N-channel enhancement type MIS transistors is equal to the sum of the number of first detecting circuit and the number of second detecting circuit. An output signal from the first detecting circuit for detecting the external power source voltage and an output signal from the second detecting circuit for detecting the internal power source voltage are applied on a one-to-one basis to gate electrodes of the plurality of N-channel enhancement type MIS transistors which are connected in series and included in the circuit for amplifying and waveform-shaping the input signals and performing the logical operation. Of the output signals from the reset signal generating means, a converted signal having the logical amplitude corresponding to the external power source voltage is supplied to the circuit block being operated by the external power source voltage. Of the output signals from the reset signal generating means, a converted signal having the logical amplitude corresponding to the internal power source voltage is supplied to the circuit block being operated by the internal power source voltage.

In a semiconductor integrated circuit device according to a fourth aspect of the present invention, the current mirror circuit of the third aspect includes a first P-channel enhancement type MIS transistor and a second P-channel enhancement type MIS transistor. A gate electrode of the first P-channel enhancement type MIS transistor and a gate electrode of the second P-channel enhancement type MIS transistor are commonly connected with each other and also connected with a drain electrode of the first P-channel enhancement type MIS transistor, thereby constructing the input terminal of the current mirror circuit. A drain electrode of the second P-channel enhancement type MIS transistor serves as the output terminal of the current mirror circuit. A source electrode of the first P-channel enhancement type MIS transistor and a source electrode of the second P-channel enhancement type MIS transistor are commonly connected with one of a plurality of power source voltages. The constant current circuit of the means for amplifying and waveform-shaping the plurality of input signals and performing the logical operation includes an N-channel depletion type MIS transistor having a gate electrode and a source electrode which are connected with the ground potential terminal.

According to the present invention, the power source voltages detecting circuits and the circuit for amplifying and waveform-shaping the output signals from the power source voltages detecting circuits in the reset signal generating circuit each adopt the constant current circuit. Therefore, even when the operating power source voltages are changed in a wide range, an absolute value of a consumption current and the amount of change thereof can be reduced. Further, the circuit for amplifying and waveform-shaping the output signals from the power source voltages detecting circuits is provided with the operational function. Therefore, a circuit area can be reduced to lower a manufacturing cost.

The N-channel depletion type MIS transistor whose gate is grounded is used for each of the constant current circuits. Therefore, a constant current circuit having a simple structure can be obtained, and a circuit area can be reduced to lower a manufacturing cost.

When a semiconductor integrated circuit device having an internal step-down circuit includes the reset signal generating circuit according to the present invention, a malfunction at a low power source voltage can be surely prevented. Thus, it is possible to realize a semiconductor integrated circuit device whose consumption current is low, circuit area is small, and cost is low.

### BRIEF DESCRIPTION OF THE DRAWINGS

In the accompanying drawings:

FIG. 1 is a block diagram showing a reset signal generating circuit according to a first embodiment of the present invention;

FIG. 2 is a circuit diagram showing an example of the reset signal generating circuit according to the first embodiment of the present invention;

FIG. 3 is a block diagram showing a reset signal generating circuit according to a second embodiment of the present invention;

FIG. 4 is a circuit diagram showing an example of the reset signal generating circuit according to the second embodiment of the present invention;

FIG. 5 is a block diagram showing an example of a semiconductor integrated circuit device using the reset signal generating circuit according to the present invention;

FIG. 6 is a block diagram showing a semiconductor integrated circuit device including the reset signal generating circuit according to the present invention and an electrically rewritable nonvolatile memory element; and

FIG. 7 is a circuit diagram showing a conventional reset signal generating circuit.

### DETAILED DESCRIPTION OF THE PREFERRED EMBODIMENTS

### First Embodiment

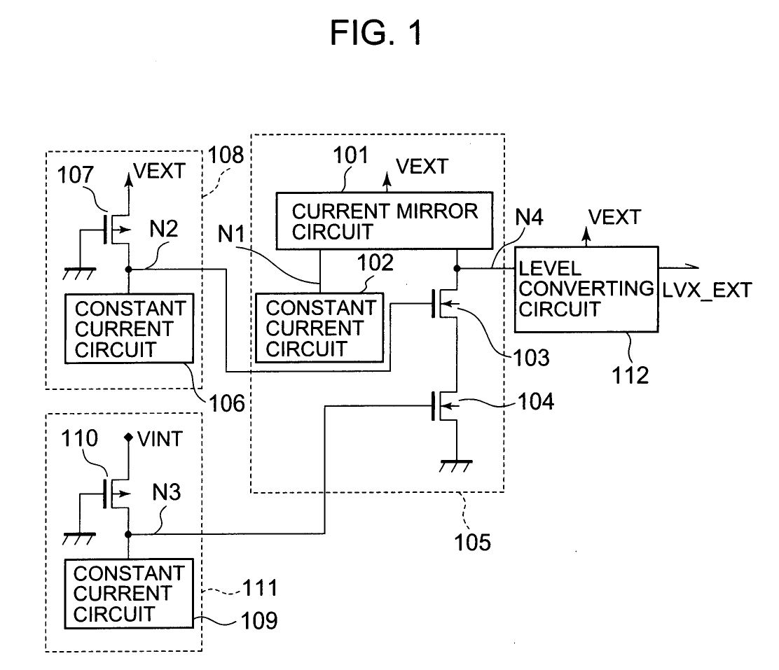

FIG. 1 is a block diagram showing a structure of a reset signal generating circuit according to a first embodiment of the present invention.

A voltage detecting section 108 for detecting an external power source voltage (VEXT) includes a P-channel enhancement type MIS transistor 107 whose gate is grounded and a constant current circuit 106. When the external power source voltage (VEXT) gradually increases from a ground potential and exceeds a threshold voltage of the P-channel enhancement type MIS transistor 107, a level of a node N2 is changed from an L-level to an H-level. When the external power source voltage gradually decreases from a high potential and becomes lower than the threshold voltage of the P-channel enhancement type MIS transistor 107, the level of the node N2 is changed from the H-level to the L-level. That is, the potential of the node N2 is changed by whether or not a current flowing through the P-channel enhancement type MIS transistor 107 is larger than a constant current value of the constant current circuit 106. Therefore, a detection voltage can be controlled by suitably adjusting a channel width or a channel length of the P-channel enhancement type MIS transistor 107, and the constant current value of the constant current circuit 106.

A voltage detecting section 111 for detecting an internal power source voltage (VINT) includes a P-channel enhancement type MIS transistor 110 whose gate is grounded and a constant current circuit 109. When the internal power source voltage (VINT) gradually increases from a ground potential and exceeds a threshold voltage of the P-channel enhancement type MIS transistor 110, a level of a node N2 is changed from an L-level to an H-level. When the external power source voltage gradually decreases from a high potential and becomes lower than the threshold voltage of the P-channel enhancement type MIS transistor 107, the level of the node N2 is changed from the H-level to the L-level. That is, the potential of the node N3 is changed by whether or not a current flowing through the P-channel enhancement type MIS transistor 110 is larger than a constant current value of the constant current circuit 109. Therefore, a detection voltage can be controlled by suitably adjusting a channel width or a channel length of the P-channel enhancement type MIS transistor 110, and the constant current value of the constant current circuit 109.

An amplifying and operating section 105 for amplifying and operating an output signal of the voltage detecting section includes a current mirror circuit 101, a constant current circuit 102, and N-channel enhancement type MIS transistors 103 and 104 connected in series. A node N4 becomes a low potential close to a ground potential only when the potentials of the node N2 and the node N3 become higher than the threshold voltages of the N-channel enhancement type MIS transistors 103 and 104. On the other hand, when at least one of the external power source voltage (VEXT) and the internal power source voltage (VINT) is equal to or smaller than a specific detection voltage, one of the node N2 and the node N3 becomes a low potential close to the ground potential. Therefore, the corresponding one of the N-channel enhancement type MIS transistors 103 and 104 is turned off, so that the potential of the node N4 is pulled up to a high-potential side by the current mirror circuit 101.

That is, the amplifying and operating section 105 for amplifying and operating the output signal of the voltage detecting section performs the logical operation equivalent to that of a NAND circuit in which the nodes N2 and N3 are input terminals and the node N4 is an output terminal.

A level converting circuit 112 converts an amplitude of a signal at the node N4, which becomes an output of the amplifying and operating section 105 for amplifying and operating the output signal of the voltage detecting section, into a logical amplitude corresponding to the external power source voltage (VEXT). Such the conversion example is not shown. However, when a power source voltage supplied to the level converting circuit 112 is not the external power source voltage (VEXT) but the internal power source voltage (VINT), it is possible that the level converting circuit 112 converts the amplitude of the signal at the node N4, which becomes the output of the amplifying and operating section 105 for amplifying and operating the output signal of the voltage detecting section, into a logical amplitude corresponding to the internal power source voltage (VINT).

In the reset signal generating circuit according to the first embodiment of the present invention, even when the external power source voltage (VEXT) and the internal power source voltage (VINT) change, a current flowing through the reset signal generating circuit is limited by the constant current circuits 102, 106, and 109. Therefore, consumption current of the reset signal generating circuit is very low even when the power source voltage is high.

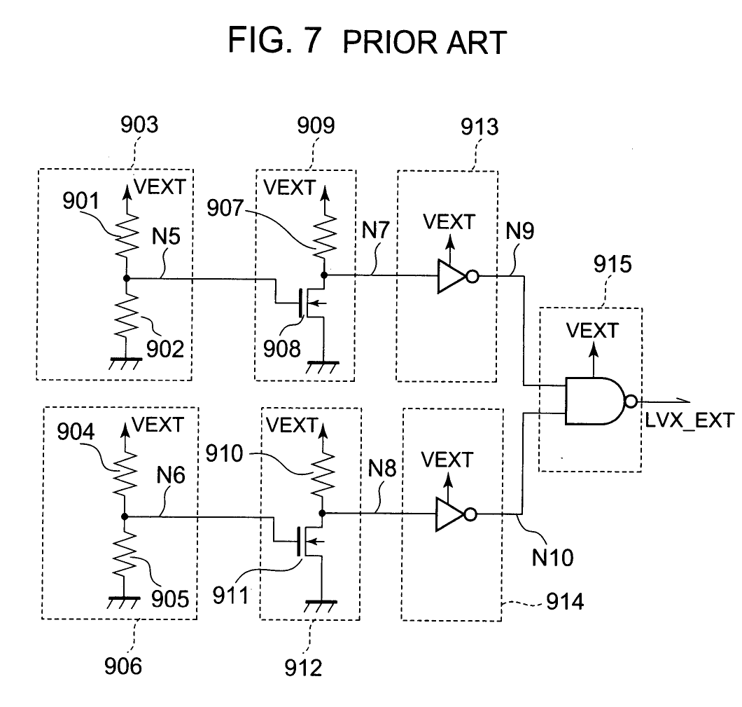

The amplifying sections 913 and 914 for amplifying the output signals from the voltage detecting sections, and the logical operation section (NAND circuit) 915 are separated from one another in the conventional reset signal generating circuit shown in FIG. 7. On the other hand, according to the first embodiment of the present invention, the amplifying section and the logical operation section are integrally provided as the amplifying and operating section 105 for amplifying and operating the output signal of the voltage detecting section, so the circuit area is smaller.

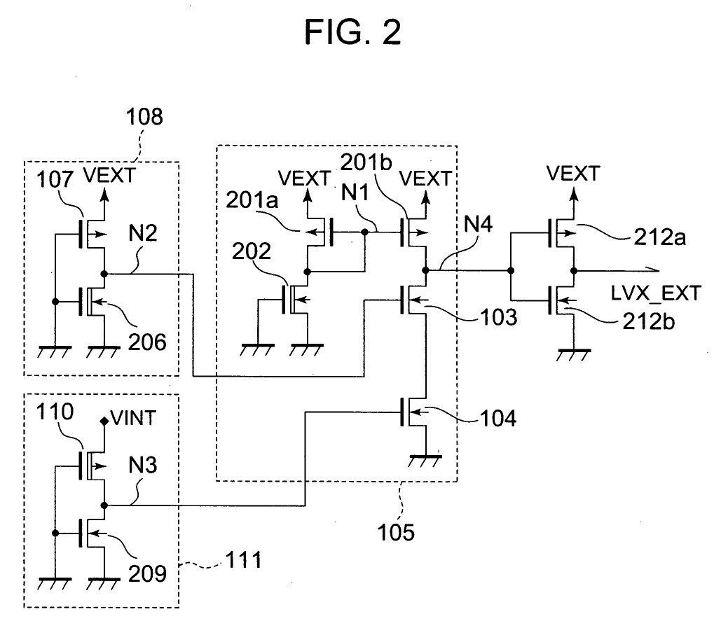

FIG. 2 is a circuit diagram showing an example of the reset signal generating circuit according to the first embodiment of the present invention.

In FIG. 2, the constant current circuits 102, 106, and 109 shown in FIG. 1 respectively include N-channel depletion type MIS transistors 202, 206, and 209 whose gate electrodes are connected with a ground potential terminal. The current mirror circuit 101 includes P-channel enhancement type MIS transistors 201a and 201b whose gate electrodes are commonly connected with each other. The commonly connected gate electrodes are connected with a drain electrode of the P-channel enhancement type MIS transistor 201a to which the drain electrode of the N-channel depletion type MIS transistor 202 which is the constant current circuit is connected. The level converting circuit 112 is composed of a CMOS inverter circuit which is operated by the external power source voltage (VEXT) including a P-channel enhancement type MIS transistor 212a and an N-channel enhancement type MIS transistor 212b.

In general, when the MIS transistors rather than the resistance elements are used as current limiting elements, a CMOS circuit can be realized in a small area to obtain the same resistance value. In addition, when the N-channel depletion type MIS transistor whose gate electrode is connected with the ground potential terminal is used, a constant current element can be obtained with a very simple structure.

Therefore, as compared with the conventional reset signal generating circuit shown in FIG. 7, the circuit structure shown in FIG. 2 makes it possible to reduce the consumption current and the circuit area.

### Second Embodiment

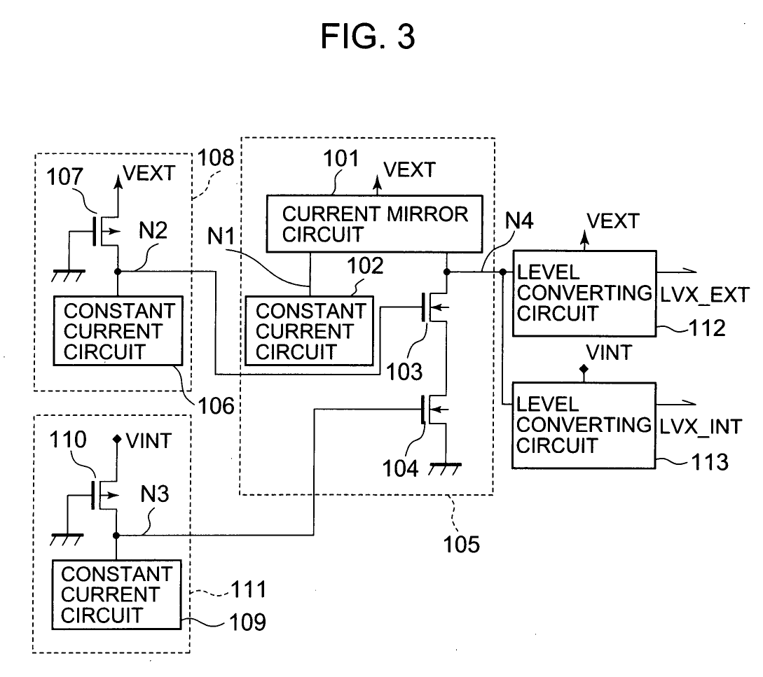

FIG. 3 is a block diagram showing a structure of a reset signal generating circuit according to a second embodiment of the present invention.

In the second embodiment, a level converting circuit 113 is provided in addition to the level converting circuit 112 in the reset signal generating circuit according to the first embodiment. The level converting circuit 112 converts the amplitude of the signal at the node N4, which becomes the output of the amplifying and operating section 105 for amplifying and operating the output signal of the voltage detecting section, into the logical amplitude corresponding to the external power source voltage (VEXT). The level converting circuit 113 converts the amplitude of the signal into a logical amplitude corresponding to the internal power source voltage (VINT).

As in the case of the first embodiment, the consumption current and the circuit area can be reduced as compared with the conventional reset signal generating circuit shown in FIG. 7.

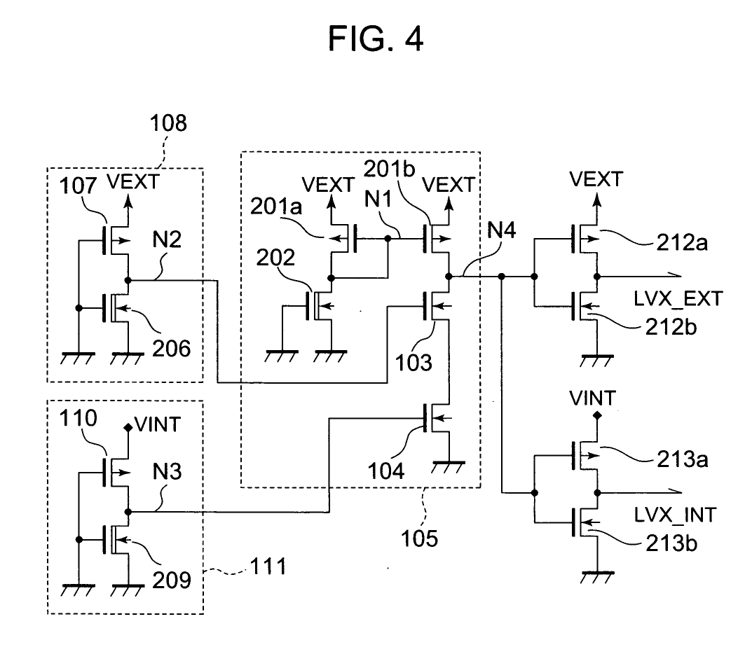

FIG. 4 is a circuit diagram showing an example of the reset signal generating circuit according to the second embodiment of the present invention.

In FIG. 4, first and second CMOS inverter circuits are provided in the reset signal generating circuit shown in FIG. 2. The first CMOS inverter circuit is used as the level converting circuit for converting the amplitude of the signal at the node N4, which becomes the output of the amplifying and operating section 105 for amplifying and operating the output signal of the voltage detecting section, into the logical amplitude corresponding to the external power source voltage (VEXT). The first CMOS inverter circuit is operated by the external power source voltage (VEXT) including the P-channel enhancement type MIS transistor 212a and the N-channel enhancement type MIS transistor 212b. The second CMOS inverter circuit is used as the level converting circuit for converting the amplitude of the signal into the logical amplitude corresponding to the internal power source voltage (VINT). The second CMOS inverter circuit includes a P-channel enhancement type MIS transistor 213a and an N-channel enhancement type MIS transistor 213b and is operated by the internal power source voltage (VINT).

As in the case shown in FIG. 2, the consumption current and the circuit area can be reduced as compared with the conventional reset signal generating circuit shown in FIG. 7.

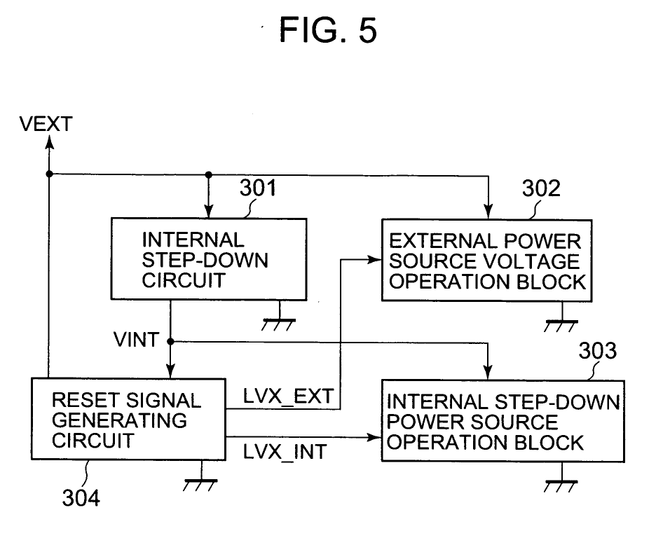

FIG. 5 is a block diagram showing an example of a structure of a semiconductor integrated circuit device using the reset signal generating circuit according to the present invention.

The semiconductor integrated circuit device shown in FIG. 5 includes an internal step-down circuit 301 for reducing the external power source voltage (VEXT) to supply the internal power source voltage (VINT) to each internal circuit, a circuit block 302 being operated by the external power source voltage (VEXT), a circuit block 303 being operated by the internal power source voltage (VINT), and a reset signal generating circuit 304.

The reset signal generating circuit 304 generates a reset signal LVX_EXT whose logical amplitude is at a logical level corresponding to the external power source voltage (VEXT) and a reset signal LVX_INT whose logical amplitude is at a logical level corresponding to the internal power source voltage (VINT). The circuit block 302 being operated by the external power source voltage (VEXT) is controlled based on the reset signal LVX_EXT. The circuit block 303 being operated by the internal power source voltage (VINT) is controlled based on the reset signal LVX_INT.

According to such the structure, a semiconductor integrated circuit device whose consumption current is low, circuit area is small, and a cost is low can be realized while a malfunction at a low power source voltage is surely prevented.

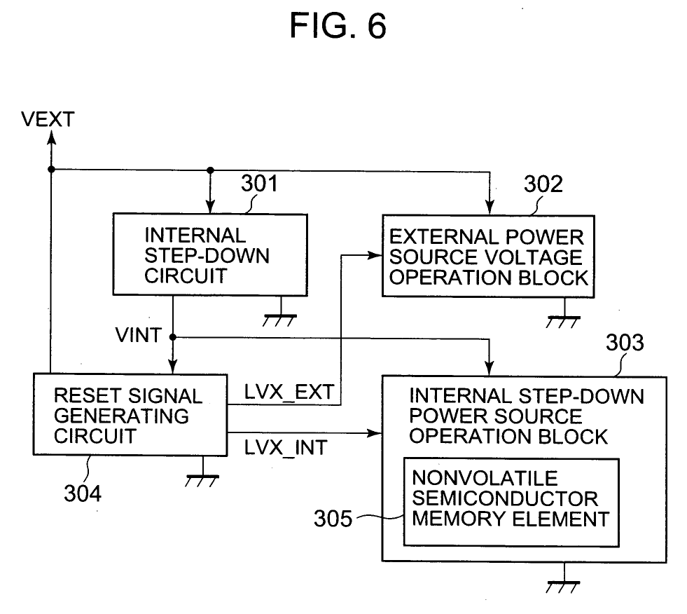

A semiconductor integrated circuit device shown in FIG. 6 includes the internal step-down circuit 301 for reducing the external power source voltage (VEXT) to supply the internal power source voltage (VINT) to each internal circuit, the circuit block 302 being operated by the external power source voltage (VEXT), the circuit block 303 being operated by the internal power source voltage (VINT), and the reset signal generating circuit 304. The circuit block 303 being operated by the internal power source voltage (VINT) includes an electrically rewritable nonvolatile semiconductor memory element 305 as a part of constituent elements.

The reset signal generating circuit 304 generates a reset signal LVX_EXT whose logical amplitude is at a logical level corresponding to the external power source voltage (VEXT) and a reset signal LVX_INT whose logical amplitude is at a logical level corresponding to the internal power source voltage (VINT). The circuit block 302 being operated by the external power source voltage (VEXT) is controlled based on the reset signal LVX_EXT. The circuit block 303 being operated by the internal power source voltage (VINT) is controlled based on the reset signal LVX_INT.

When one of the external power source voltage (VEXT) and the internal power source voltage (VINT) is equal to or smaller than specific voltage, the circuit block 302 being operated by the external power source voltage (VEXT) and the circuit block 303 being operated by the internal power source voltage (VINT) are controlled based on the reset signal LVX_EXT and the reset signal LVX_INT, respectively, which are output signals of the reset signal generating circuit 304, such that a write operation to the electrically rewritable nonvolatile semiconductor memory element 305 is disabled.

In the case where a write control circuit becomes unstable, such as the case where a power source of the semiconductor integrated circuit device is turned on or off, it is likely to produce unreadable data by write error in the nonvolatile semiconductor memory element. However, when such the structure is used, a semiconductor integrated circuit device whose consumption current is low, circuit area is small, and a cost is low can be realized while a malfunction at low power source voltage is surely prevented.

In FIG. 6, the output signals of the reset signal generating circuit 304 are used to control both the circuit block 302 being operated by the external power source voltage (VEXT) and the circuit block 303 being operated by the internal power source voltage (VINT), thereby preventing write error to the nonvolatile semiconductor memory element. If one of the circuit blocks 302 and 303 is reset to eliminate the unstable state of the write control circuit for the nonvolatile semiconductor memory element, only one of the reset signal LVX_EXT and the reset signal LVX_INT may be outputted.

What is claimed is:

1. A reset signal generating circuit, comprising:
a plurality of voltage detecting circuits for detecting voltages;
a logical operation circuit for amplifying and waveform-shaping output signals outputted from the voltage detecting circuits and performing a logical operation therebetween; and
a level converting circuit for converting an amplitude of an output signal outputted from the logical operation circuit into a specific logical amplitude, wherein:
each of the voltage detecting circuits includes:
a first constant current circuit; and
a P-channel enhancement type MIS transistor whose source electrode is connected with a terminal for a voltage to be detected, whose gate electrode is connected with a ground potential terminal, and whose drain electrode is connected with the first constant current circuit;
the logical operation circuit includes:
a current mirror circuit including at least one input terminal and at least one output terminal;
a second constant current circuit including an output terminal connected with the input terminal of the current mirror circuit; and
a plurality of N-channel enhancement type MIS transistors connected in series with the output terminal of the current mirror circuit, the number of N-channel enhancement type MIS transistors being equal to the number of voltage detecting circuits; and
the output signals from the voltage detecting circuits are applied to gate electrodes of the N-channel enhancement type MIS transistors connected in series in the logical operation circuit on a one-to-one basis.

2. A reset signal generating circuit according to claim 1, wherein each of the first constant current circuit and the second constant current circuit comprises an N-channel depletion type MIS transistor whose gate electrode and source electrode are connected with the ground potential terminal.

3. A reset signal generating circuit according to claim 1, wherein the level converting circuit is connected to the output terminal of the current mirror circuit.

4. A reset signal generating circuit according to claim 1, wherein the level converting circuit comprises a plurality of level converting circuit provided based on the voltages detected by the voltage detecting circuits.

5. A semiconductor integrated circuit device, comprising:
a first circuit being operated by an external power source voltage;
a second circuit being operated by an internal power source voltage produced from the external power source voltage; and
the reset signal generating circuit according to claims 1.

6. A semiconductor integrated circuit device according to claims 5,
wherein the second circuit comprises an electrically rewritable nonvolatile memory element.
